(19) United States
(12) Patent Application Publication
(10) Pub. No.: US 2008/0277737 A1
(43) Pub. Date: Nov. 13, 2008

(54) Method of Manufacturing a Semiconductor Device and Semiconductor Device Obtained with Such a Method

(75) Inventor: Vijayaraghavan Madakasira, Louvain (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/093,652

(22) PCT Filed: Oct. 27, 2006
(86) PCT No.: PCT/IB2006/053955

§ 371 Date: May 21, 2008

(30) Foreign Application Priority Data
Nov. 16, 2005 (EP) 05110790.2
Oct. 27, 2006 (IB) PCT/IB2006/053955

(51) Int. Cl. H01L 21/768; H01L 29/78

(52) U.S. Cl. 257/382; 438/675; 257/E21.591; 257/E29.255

(57) ABSTRACT

The invention relates to a method of manufacturing a semiconductor device (10) with a substrate (11) and a semiconductor body (12) which is provided with at least one semiconductor element (E), wherein on the surface of the semiconductor body (12) a mesa-shaped semiconductor region (1) is formed, an insulating layer (2) is deposited over the mesa-shaped semiconductor region (1) having a smaller thickness on top of the mesa-shaped semiconductor region (1) than in a region (3) bordering the mesa-shaped semiconductor region (1), subsequently a part of the insulating layer (2) on top of the mesa-shaped semiconductor region (1) is removed freeing the upper side of the mesa-shaped semiconductor region (1), and subsequently a conducting layer (4) contacting the mesa-shaped semiconducting region (1) is deposited over the resulting structure. According to the invention the insulating layer (2) is deposited using a high-density plasma deposition process. Such a process is particular suitable for the manufacturing of devices with small mesa-shaped regions (1) e.g. in the form of nano wires. Preferably a thin further insulating layer (5) is deposited using another, conformal deposition process before the insulating layer (2) is deposited.

The invention relates to a method of manufacturing a semiconductor device with a substrate and a semiconductor body which is provided with at least one semiconductor element, wherein on the surface of the semiconductor body a mesa-shaped semiconductor region is formed, an insulating layer is deposited over the mesa-shaped semiconductor region having a smaller thickness on top of the mesa-shaped semiconductor region than in a region bordering the mesa-shaped semiconductor region, subsequently a part of the insulating layer on top of the mesa-shaped semiconductor region is removed freeing the upper side of the mesa-shaped semiconductor region, and subsequently a conducting layer contacting the mesa-shaped semiconducting region is deposited over the resulting structure. The invention also relates to a semiconductor device obtained with such a method.

Such a method is very suitable for making semiconductor devices like ICs (=Integrated Circuit) or other devices such as discrete devices comprising nano-wire elements. Here with a nano wire a body is intended having at least one lateral dimension between 0.5 and 100 nm and more in particular between 1 and 50 nm. Preferably a nano-wire has dimensions in two lateral directions that are in the said ranges. It is further noted here that contacting extremely small dimensions in semiconductors is a challenging technique in semiconductor processing. However, although the mesa-shaped semiconductor region is intended to comprise in particular a nano wire, the invention is also applicable to other mesa shaped semiconductor regions that have other dimensions. Mesa-shaped of a region means that the region forms a protrusion on the surface of the semiconductor body.

A method as mentioned in the opening paragraph is known from the US patent application that has been published under number 2003/0189202 on Oct. 9, 2003. In this document a number of mesa shaped semiconductor regions comprising single crystal nano wires are provided on a silicon substrate. After the nano wire growth, an insulating layer is deposited over the nano wire(s) such that the thickness of said layer on top of said nano wire is smaller than the thickness of said layer in regions bordering said nano wire, e.g. regions between two neighboring nano wires. The insulating layer is deposited using CVD (=Chemical Vapor Deposition) or a spin on glass or spray on polymer layer technique. The insulating layer is subsequently planarized using e.g. CMP (=Chemical Mechanical Polishing). The upper surface of a nano wire, which is made free in this way, is subsequently covered with e.g. a conducting layer like a metal layer. All kinds of semiconductor devices like a sensor or a field emitter for displays may be formed in this way according to said document.

A drawback of such a method is that it is less suitable for semiconductor devices like transistors comprising e.g. nano wires for contacting source or drain region or emitter or collector regions of transistors. In particular CVD results in a too uniform thickness of an insulating layer and spin on or spray on techniques are less suitable for devices having protrusions with very small lateral dimensions like in the case of delicate protrusions in the form of nano wires. This in view of the processing conditions involved like the temperature.

It is therefore an object of the present invention to avoid the above drawbacks and to provide a method, which is suitable for the manufacturing of semiconductor devices comprising transistors that comprise very small active areas with protrusions like in particular nano wires.

To achieve this, a method of the type described in the opening paragraph is characterized in that the insulating layer is deposited using a high-density plasma deposition process. Due to the simultaneous deposition and sputtering, high-density plasma deposition has the property of self planarizing where e.g. oxide is deposited over arrays of very fine structures like nano wires. Thus, the thickness on top of such nano wire may be considerably smaller than the thickness obtained on features with (much) larger lateral dimensions. Moreover, the material obtained in this way on top of the mesa can be easily etched for freeing the upper side of the mesa shaped region (nano wire) while the side faces of the mesa still remain isolated due to the tapered character of an insulating layer deposited in such a way. Furthermore this allows for the use of a simple etching step to make the surface of the mesa free, such step being possible without damaging or altering the structure of the (top of the) mesa. The latter otherwise is easily damaged or changed in the case of a nano wire.

With a controlled fine tuning of the ratio of the deposition rate and the sputtering rate during the HDP (oxide) deposition, the thickness ratio of an insulating layer on top of a small area structure and on top of a large area can be well controlled.

In a preferred embodiment the upper side of the mesa-shaped semiconducting region is freed using a, preferably wet, etching step. Such an etching step can easily be extremely selective which again is very favorable for not damaging or altering the upper portion of the mesa, in particular of a nano wire. Also the variation in height of the nano wires/mesas of which the top surface is made free, can be small. A process like CMP might easily result in a spread of this height over a large wafer. If the insulating layer comprises silicon dioxide, an etchant based on hydrogen fluoride may be used. In case of an insulating layer of silicon nitride an etchant based on hot phosphoric acid may be used.

In a further preferred embodiment that before the deposition of the insulating layer a further insulating layer is deposited with a smaller thickness than the thickness of the insulating layer and which is deposited using a conformal deposition process. Such a further insulating layer protects the mesa shaped semiconductor region against changes of shape or surface that may occur during the back etching at the beginning of the high-density plasma deposition of the insulating layer. A suitable thickness of such a further insulating layer may be between 5 and 25 nm, while the insulating layer than has a bulk thickness of e.g. about the height of the mesa shaped semiconductor region that may vary between e.g. 50 nm and 500 nm. A suitable process for such a uniform/conformal further insulating layer is CVD, e.g. using TEOS (=Tetra Ethyl Ortho Silicate) in case of a further insulating layer of silicon dioxide.

If both the insulating and further insulating layer comprises the same material, the freeing of the top side of the mesa can be accomplished with a single etching step. Silicon dioxide is a very suitable material for that purpose.

In a further advantageous embodiment after freeing the upper side of the mesa-shaped semiconductor region a contact region is formed on the surface contacting the mesa-shaped semiconductor region, comprising a metal silicide and having larger lateral dimensions than the mesa-shaped semiconductor region. Such a contact region is particular suitable for contacting source/drain regions of a field effect transistor or emitter/collector regions of a bipolar transistor.

Preferably the contact region is formed by deposition of polycrystalline silicon layer and a metal layer, at least the polycrystalline silicon layer being patterned before the formation of the metal silicide. In this way, the silicide formation can be self aligned. The metal layer can be deposited before the formation of the patterned polycrystalline layer or after or both before and after. In the latter case, two metal layers are actually used to form the silicide.

However, preferably the metal layer is deposited after the deposition of the patterned polycrystalline silicon layer. In this way, the later uniformity of the composition of the metal silicide in the contact region can be high. Moreover, in case of a highly doped polycrystalline silicon layer, additional doping atoms can be driven from such layer into the—upper part of the—nano wire that e.g. forms the emitter or collector of a bipolar transistor. Removal of the remainder of the metal layer, either on top of the contact region but in any case outside said region can be easily accomplished using selective (wet) etching. Doping the nano wire by out diffusion of doping atoms from the polycrystalline silicon layer into the nano wire is preferably done by a RTA (=Rapid Thermal Anneal) step. Moreover, in this preferred embodiment an additional stronger doping of the nano wire can be obtained during the silicidation step since the so-called snow-plow effect pushes doping atoms to the silicon region that borders the moving metal-silicide silicon interface.

Preferably the thickness of the insulating and the further insulating layers is chosen to be about equal to the height of the mesa-shaped semiconductor region. Thanks to the tapered nature of the insulating region, the side faces of the mesa can still be covered by insulating material after the upper side of the mesa has been freed by etching.

For the semiconductor element preferably a transistor is chosen. The mesa shaped semiconductor region, in particular in the form of a nano wire, may form part of a contact of source/drain regions of a field effect transistor or may form (a part of) an emitter or collector region of a bipolar transistor.

Finally, the present invention also comprises a semiconductor device obtained by a method according to the invention.

These and other aspects of the invention will be apparent from and elucidated with reference to the embodiments described hereinafter, to be read in conjunction with the drawing, in which

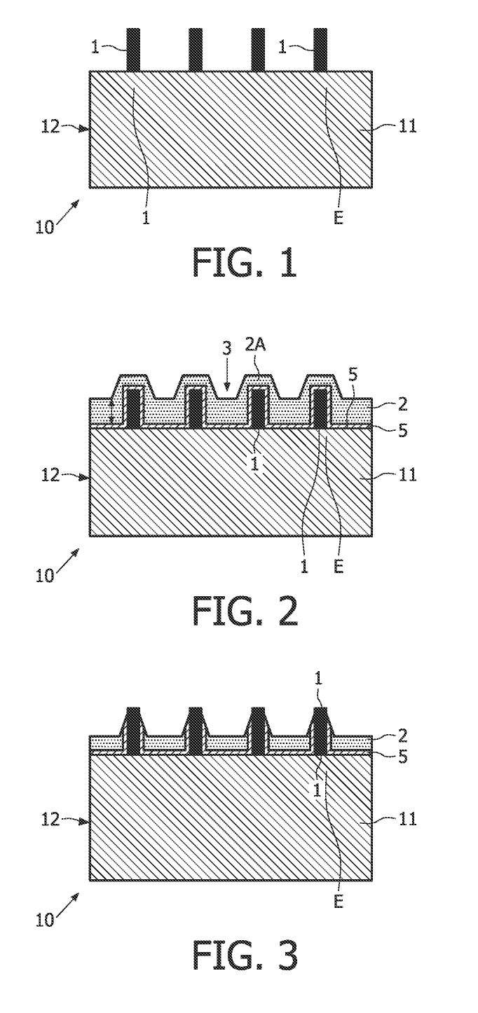

FIGS. 1 through 10 are sectional views of a semiconductor device at various stages in its manufacture by means of a method in accordance with the invention, and

FIG. 11 shows the thickness d of a high density plasma deposited silicon oxide on a pillar as a function of the diameter D of the pillar.

The Figures are diagrammatic and not drawn to scale, the dimensions in the thickness direction being particularly exaggerated for greater clarity. Corresponding parts are generally given the same reference numerals and the same hatching in the various Figures.

FIGS. 1 through 10 are sectional views of a semiconductor device at various relevant stages in its manufacture by means of a method in accordance with the invention. The semiconductor device to be manufactured may contain already at the stage in advance of FIG. 1 a semiconductor element that may have been formed in a usual manner. The element may be e.g. a field effect transistor or a bipolar transistor. The mesa-shaped region that is formed in the method of this example may be e.g. a contact structure for the source/drain region of field effect transistor or the emitter of a bipolar transistor the collector region in an inverted bipolar transistor. The features of such a transistor are for reasons of simplicity not shown in the drawing.

In a first relevant step of the manufacture of the device 10 (see FIG. 1) a silicon substrate 11 forming a silicon semiconductor body 12 in which a semiconductor element E, e.g. a field effect or bipolar transistor, has already been (largely) formed, is provided mesa-shaped semiconductor region 1, here nano wires 1 comprising silicon. These wires 1 can be formed e.g. by photolithography and etching of a uniformly deposited layer but also by a selective deposition technique as described in e.g. “Vapor-liquid-solid mechanism of single crystal growth” by R. S. Wagner and W. C. Ellis that has been published in Applied Physics Letters, vol. 4, no. 5, 1 march 1964, pp 89-90. In this example the height of the pillar 1 is about 500 nm and its diameter is about 50 nm.

Subsequently (see FIG. 2) a thin layer 5 of silicon dioxide is deposited using CVD (=Chemical Vapor Deposition) and TEOS (=Tetra Ethyl Ortho Silicate) as source material. In this example the layer 5 is 10 nm thick and its thickness is substantially the same at every location. The function of this layer 2 is to form an anchor and a protective shield for the thin pillar 1 against sputtering in a subsequent deposition process of an insulating layer 2 of again silicon dioxide. However the deposition is now performed using a high density plasma deposition. In this process simultaneous deposition and sputtering takes place, the deposition prevailing. Such a specific deposition process has a self-planarizing property as can be seen in FIG. 2 since the thickness of insulating layer 2 is thinner on top of the pillars 1 than in bordering regions 3. In this example the thickness on top of the pillars 1 is about 100 nm which is about 400 nm less than the thickness in the bordering region 3 which is about 500 nm. Typical for the deposition process uses are also the tapering 15 obtained in the insulating layer 2 alongside the pillar 1, corresponding with a 45° sidewall angle.

Next (see FIG. 3) parts of the insulating and further insulating layers 2,5 on top of the pillar 1 are removed by an etchant that is selective towards silicon and comprises in this example an etchant on the base of hydrogen fluoride, possibly buffered. The etching is done on a time base using the known etching rate.

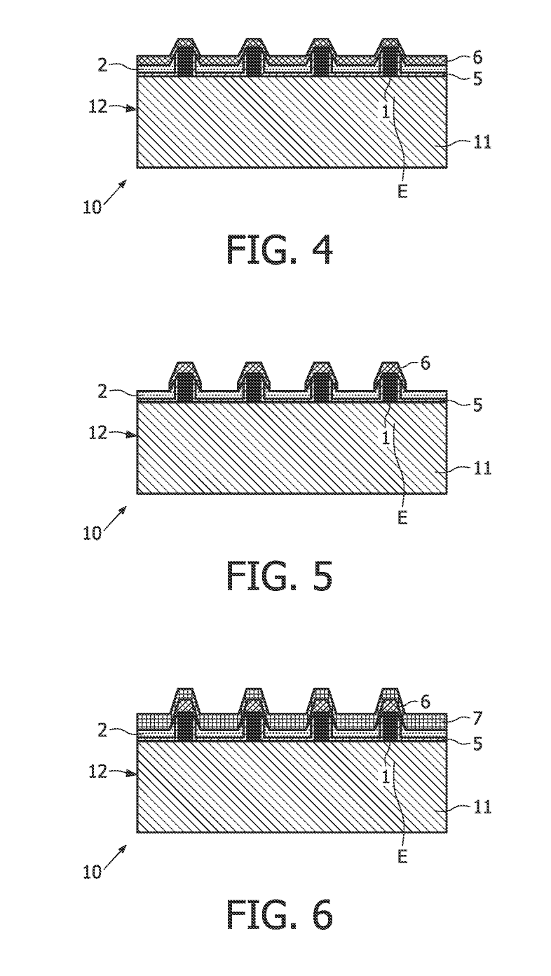

Subsequently (see FIG. 4) a 60 nm thick layer 6 of polycrystalline silicon is deposited over the structure. This is done using e.g. CVD as the deposition technique.

Next (see FIG. 5) the polycrystalline silicon layer 6 is patterned using photolithography and (dry) etching. These steps are not shown separately. The diameter of the patterned poly island 6 is in this example about 500 nm and can have in general about the size of the active area.

Now (see FIG. 6) a metal layer 7, here a nickel layer having a thickness of 30 nm, is deposited over the structure, e.g. using sputtering or a vapor deposition technique. Then the structure is subjected to a heating treatment at a temperature in the range of 280 to 400° C., in this example at 300° C. in a furnace. By this treatment the polycrystalline silicon regions 6 react with the metal layer 7 to form a metal silicide, in this example nickel mono silicide.

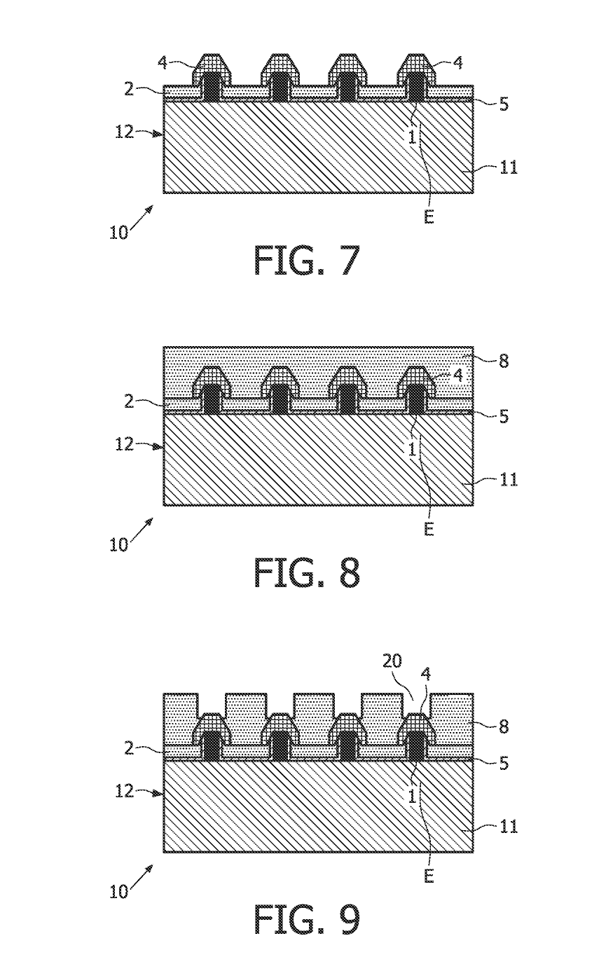

The resulting structure (see FIG. 7) shows nickels silicide contact regions 4 that have been formed on top of the pillars 1 in a self-aligned manner. The remaining parts of the nickel layer 7 outside the contact regions 4 have been removed by selective etching.

Next (see FIG. 8) a PMD (=Pre Metal Dielectric) layer 8 is deposited comprising silicon dioxide having a thickness of e.g. 1000 nm and using CVD.

After this step (see FIG. 9) contact holes 20 are formed in the PMD layer 8 using photolithography and etching.

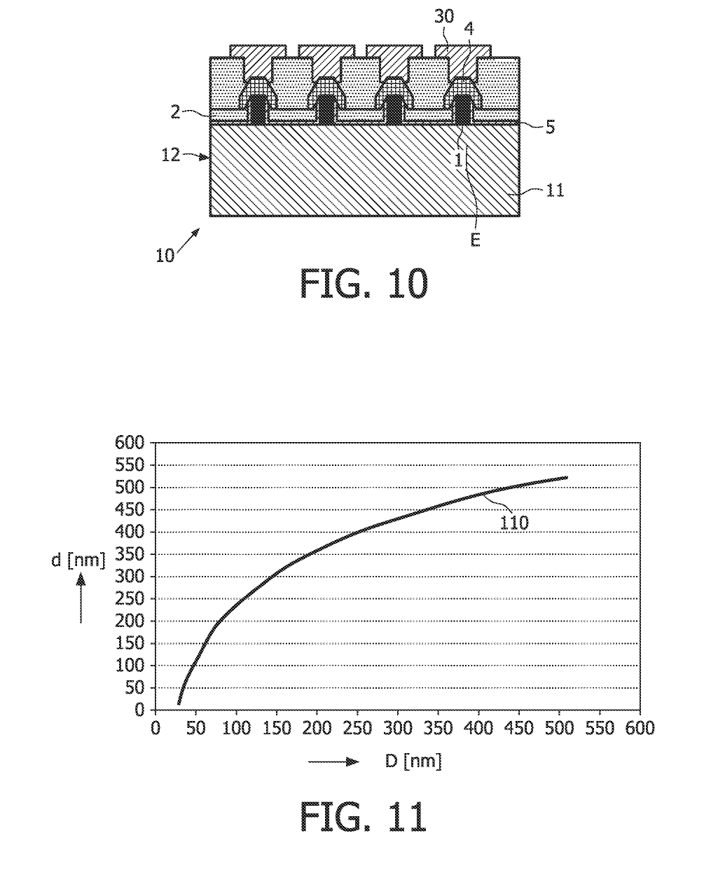

Finally (see FIG. 10) a metal layer 30, e.g. of aluminum, is deposited and patterned in order to contact the larger dimension silicide areas 4. Individual devices 10 that are suitable for mounting are obtained after applying a separation technique like etching or sawing.

The effect of the choice of the high density plasma and the geometry of the surface on which the deposition takes place will be illustrated once more below.

FIG. 11 shows the thickness d of a high density plasma deposited silicon oxide on a pillar as a function of the diameter D of the pillar. The results of this Figure are obtained for a silicon dioxide layer that deposited on a flat silicon substrate has a thickness of 500 nm. Curve 110, showing the thickness d of the deposit on a structured silicon surface comprising pillars of silicon with a diameter of D, shows that for a pillar diameter of about 500 nm the thickness of the deposit is substantially the same as in the case of a deposit on a flat wafer. For smaller diameters D the thickness d of the deposit on top of the pillar gradually decreases. E.g. for a pillar having a diameter D of about 50 nm, said thickness d is about 100 nm, which is about 400 nm less than the thickness of the deposit on a flat wafer and also of the deposit in between two pillars, provided that the distance between two neighboring pillars is large enough, e.g. larger than about 500 nm.

It will be obvious that the invention is not limited to the examples described herein, and that within the scope of the invention many variations and modifications are possible to those skilled in the art.

For example it is to be noted that the invention is not only suitable for the manufacture of a discrete device like a transistor but for the manufacture of ICs like (C)MOS or BI(C)MOS ICs but also bipolar ICs. Each nano wire region can for part of a single (part of a) device but it also is possible to use a plurality of nano wires forming a part of a single device or of a single region of a device.

Furthermore it is noted that various modifications are possible with respect to individual steps. For example other deposition techniques can be selected in stead of those used in the example. The same holds for the materials selected. Thus, the (further) insulating layer could be made of e.g. silicon nitride.

Finally it is to be emphasized again that the present invention allows for making a device with a mesa-shaped region with a very small lateral dimension like in the case of a nano wire that on the one hand contains a large doping level while it on the other hand can be provided with a large contacting pad.

1. Method of manufacturing a semiconductor device with a substrate and a semiconductor body which is provided with at least one semiconductor element, wherein on the surface of the semiconductor body a mesa-shaped semiconductor region is formed, an insulating layer is deposited over the mesa-shaped semiconductor region having a smaller thickness on top of the mesa-shaped semiconductor region than in a region bordering the mesa-shaped semiconductor region, subsequently a part of the insulating layer on top of the mesa-shaped semiconductor region is removed freeing the upper side of the mesa-shaped semiconductor region, and subsequently a conducting layer contacting the mesa-shaped semiconducting region is deposited over the resulting structure, characterized in that the insulating layer is deposited using a high-density plasma deposition process.

2. Method according to claim 1, characterized in that the upper side of the mesa-shaped semiconducting region is freed using a, preferably wet, etching step.

3. Method according to claim 1, characterized in that before the deposition of the insulating layer a further insulating layer is deposited with a smaller thickness than the thickness of the insulating layer and which is deposited using a conformal deposition process.

4. Method according to claim 3, characterized in that the further insulating layer is deposited using a chemical vapor deposition process.

5. Method according to claim 3, characterized in that for the material of the insulating layer and for the material of the further insulating layer silicon dioxide is used.

6. Method according to claim 5, characterized in that after freeing the upper side of the mesa-shaped semiconductor region a contact region is formed on the surface contacting the mesa-shaped semiconductor region, comprising a metal silicide and having larger lateral dimensions than the mesa-shaped semiconductor region.

7. Method according to claim 6, characterized in that the contact region is formed by deposition of polycrystalline silicon layer and a metal layer, at least the polycrystalline layer being patterned before the formation of the metal silicide.

8. Method according to claim 7, characterized in that the metal layer is deposited over the patterned polycrystalline layer and the remainder of the metal layer is removed by selective etching.

9. Method according to claim 8, characterized in that the thickness of the insulating and the further insulating layers is chosen about equal to the height of the mesa-shaped semiconductor region.

10. Method according to claim 9, characterized in that for the mesa-shaped semiconductor region a nano-wire is chosen.

11. Method according to claim 10, characterized in that for the semiconductor element a transistor is chosen.

12. Method according to claim 11, characterized in that the mesa-shaped semiconductor region forms the emitter or collector of a bipolar transistor.

13. Method according to claim 11, characterized in that the mesa-shaped semiconductor region is used to form a contact to a source or drain of a field effect transistor.

14. Semiconductor device obtained by a method according to claim 13.
